(19) United States
(12) Patent Application Publication
(10) Pub. No.: US 2011/0203641 A1
(43) Pub. Date: Aug. 25, 2011

(54) Nighttime Solar Panel

(76) Inventor: Kim Meghan Tran, Houston, TX (US)

(21) Appl. No.: 13/032,190

(22) Filed: Feb. 22, 2011

Related U.S. Application Data
(60) Provisional application No. 61/306,458, filed on Feb. 20, 2010.

(51) Int. Cl. H01L 31/058

(52) U.S. Cl. 136/248

(57) ABSTRACT

Embodiments of the present disclosure provide an improved solar panel that will produce electricity at night. The improved solar panel generally includes an array of photovoltaic cells, a thermally-conductive, rigid backing, and an array of thermocouples sandwiched between and in thermal contact with the array of photovoltaic cells and the thermally conductive, rigid backing.

### CLAIM OF PRIORITY

This application claims the benefit of priority from U.S. Provisional Patent Application Ser. No. 61/306,458 filed on Feb. 20, 2010 and entitled “Nighttime Solar Panel,” which is fully incorporated herein by reference for all purposes.

### FIELD

Certain embodiments of the present disclosure generally relate to a method and apparatus for generating electricity and, more particularly, to an improved solar panel incorporating an array of thermal electric devices to utilize the nighttime radiation cooling effect to generate electricity at night.

### BACKGROUND

While the early 19th century saw rapid progress in electrical science, it wasn't until the late 19th century that electricity turned from a scientific curiosity into an essential tool for modern life. Generating electricity requires transforming other forms of energy. Of the several means of directly transforming other forms of energy into electrical energy, the transformation of light into electrical energy (i.e., the photoelectric effect) has been of interest for at least 125 years. Though the photoelectric effect was first recognized in 1839 and the first solar cell was built in 1883, it wasn't until 1954 that a modern photovoltaic cell was developed at Bell Laboratories. However, cells were initially developed for toys and other minor uses, as the cost of the electricity they produced was very high. In relative terms, a cell that produced 1 watt of electrical power in bright sunlight cost about $250, in contrast to $2 or $3 for 1 watt from a coal plant.

In the last 50 years, generating electricity by photovoltaic devices has become much more common as more solar panels are manufactured and the prices of solar panels drop. This clean, efficient source of energy is not without its drawbacks, however. Unfortunately, electricity from solar panels has generally been found to be variable and inefficient since clouds and nightfall stops or dramatically reduces the production of electricity from solar cells. Many installations use batteries to store electricity from solar panels, mitigating the variability problem. By oversizing solar panel arrays to generate enough energy during the sunlight hours to meet operational needs with enough surplus to charge the batteries, demand for an entire 24 hour period may be met.

### SUMMARY

Certain embodiments provide an improved solar panel. The improved solar panel generally includes an array of photovoltaic cells, a thermally-conductive, rigid backing, and an array of thermocouples sandwiched between and in thermal contact with the array of photovoltaic cells and the thermally conductive, rigid backing.

Certain embodiments provide a solar power generation system. The solar power generation system generally includes a plurality of solar panels, each panel including an array of photovoltaic cells, a thermally-conductive, rigid backing, and one or more thermopiles sandwiched between and in thermal contact with the array of photovoltaic cells and the thermally-conductive, rigid backing, one or more support structures configured to elevate and position the plurality of solar panels, and a control unit configured to alter the orientation of the one or more support structures.

Certain embodiments provide a solar power generation system. The solar power generation system generally includes a plurality of solar panels, each panel including an array of photovoltaic cells, a thermally-conductive, rigid backing, and one or more thermopiles sandwiched between and in thermal contact with the array of photovoltaic cells and the thermally-conductive, rigid backing and one or more roof mountable support structures.

### BRIEF DESCRIPTION OF THE DRAWINGS

So that the manner in which the above-recited features of the present disclosure can be understood in detail, a more particular description, briefly summarized above, may be had by reference to embodiments, some of which are illustrated in the appended drawings. It is to be noted, however, that the appended drawings illustrate only certain typical embodiments of this disclosure and are therefore not to be considered limiting of its scope, for the description may admit to other equally effective embodiments.

FIG. 1 is an isometric, cutaway view illustrating an exemplary embodiment of the present disclosure.

FIG. 2 illustrates an array of thermoelectric modules electrically coupled in series.

FIG. 3 illustrates a side perspective view of a thermoelectric module (TEM).

### DETAILED DESCRIPTION

It is known that every object radiates thermal energy. For example, an object with a first thermal energy placed in a room with a second thermal energy will radiate thermal energy into any other objects in the room in thermal contact with the object, including the air. These other objects absorb the radiated energy, radiate energy back, and eventually all objects in the room arrive at approximately the same thermal energy, while collectively continuing to radiate.

A natural phenomenon called nocturnal radiation cooling has been studied as a way to help reduce the electricity demand of a residence. An object placed outside on a cloudless night will give off thermal energy through radiation but will receive almost no radiation from deep space. While the sides of the object facing the earth will give off and receive radiation, as described above, and eventually reach a stead state thermal energy, the side facing deep space will become much cooler than the other sides. This effect is the reason why frost forms on the top of automobiles on nights when the ambient air temperature is still above freezing.

Moreover, this effect can be used to generate electricity by means of a thermocouple. A thermocouple is a pair of dissimilar conductors joined at two points to form a closed circuit so as to produce an electric current when the junctions are at different temperatures. A solar panel placed outside at night may have one side facing deep space which is substantially cooler than the opposite side which is facing the earth or in thermal contact with an object of a different thermal energy (e.g., a building).

Embodiments of the present, propose coupling an array of thermocouples (i.e., a thermopile) within traditional solar cells to use the thermal gradient associated with nocturnal radiation cooling. Such a coupling can improve efficiency and reduce electric variability by increasing the amount of time a solar panel generates electricity, as will be described below.

### AN EXEMPLARY IMPROVED SOLAR PANEL

In the following, reference is made to embodiments of the present disclosure. However, it should be understood that the present disclosure is not limited to specific described embodiments. Instead, any combination of the following features and elements, whether related to different embodiments or not, is contemplated to implement and practice the present disclosure. Furthermore, in various embodiments the disclosure provides numerous advantages over the prior art. However, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the present disclosure” shall not be construed as a generalization of any inventive subject matter disclosed herein and shall not be considered to be an element or limitation of the appended claims except where explicitly recited in a claim(s).

One embodiment of the disclosure utilizes the nocturnal radiation cooling effect to provide a thermal gradient on the upper and lower surfaces of a solar panel exposed to the night sky to generate electricity through strategically placed thermocouples in the solar panel. If a thermocouple is placed so that one of the pair of junctions is exposed to (or in thermal contact with) the top side of the solar panel and the other junction is exposed to, or in thermal contact with, the bottom side of the solar panel, then current will flow from one junction to the other.

Certain embodiments of the present disclosure use a collection of thermoelectric modules (TEMs) attached to a rigid heat conducting surface (e.g., a thin sheet of metal) and covered with photovoltaic cells. Certain modules may be sized to function as a 12 volt battery charger. The solar cells may generate electricity during the day and the TEMs may generate electricity at night. Each TEM is a collection of thermocouples wired in series and may be embedded in a ceramic or silicon chip. In certain embodiments, all of the TEMs are wired in series so that one pair of wires provides the electrical output from the entire collection of thermocouples.

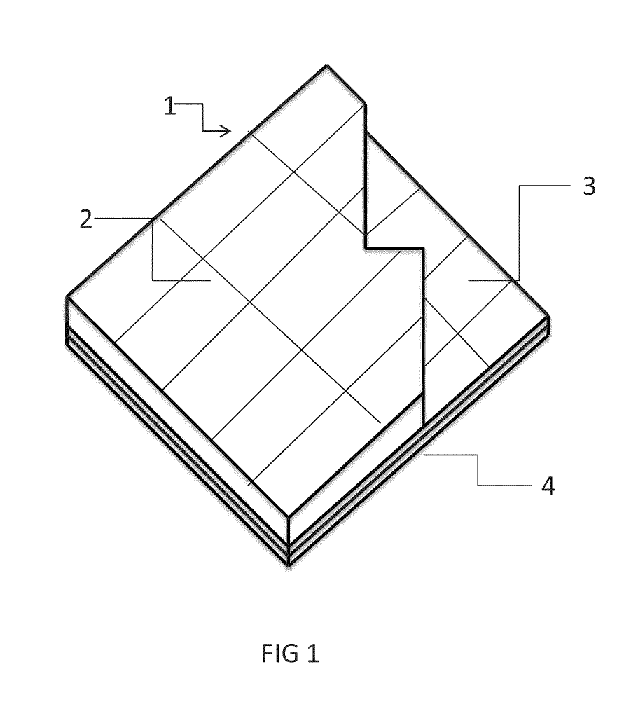

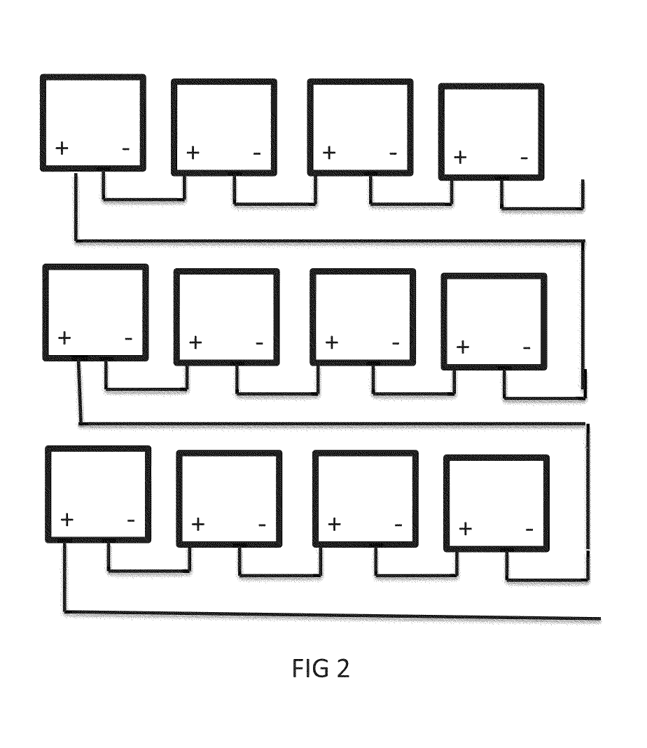

FIG. 1 is an isometric, cutaway view illustrating an exemplary embodiment of the present disclosure. In their most basic form, embodiments of the present disclosure describe an improved solar panel 1 including an array of TEMs 3 sandwiched between a rigid backing 4 and an array of photovoltaic cells 2. In certain embodiments, the rigid backing 4 may be made of aluminum, copper, gold, silver, or other appropriate material that provides support and some level of thermal conductivity. In addition, the backing 4 may provide the necessary connectivity for a stand or other mechanism that will properly orient the face of the panel to achieve optimal power production. This backing may then be covered with an array TEMs 3 that are wired in series, as shown in FIG. 2. Finally, a layer of photovoltaic cells 2 may be applied on top of the array of TEMs 3. In certain embodiments, the photovoltaic cells 2 may include monocrystalline silicon, multicrystalline silicon, or ribbon silicon.

In one embodiment, each individual TEM may measure 4 cm×4 cm×0.4 cm, and the array of TEMs may be 22×23 yielding a total of 506 TEMs covering a 3 ft×3 ft×0.25 inch aluminum backing 4. In this embodiment, the layer of photovoltaic cells 2 may be selected from a collection of commercially available, flexible 15.4 volt solar panels that provided approximately 1 amp at 15.4 volts in full sunlight. During testing of this embodiment, the 506 TEMs produced 33 milliamps at 15.2 volts on a clear night with a temperature gradient of 10 degrees Fahrenheit.

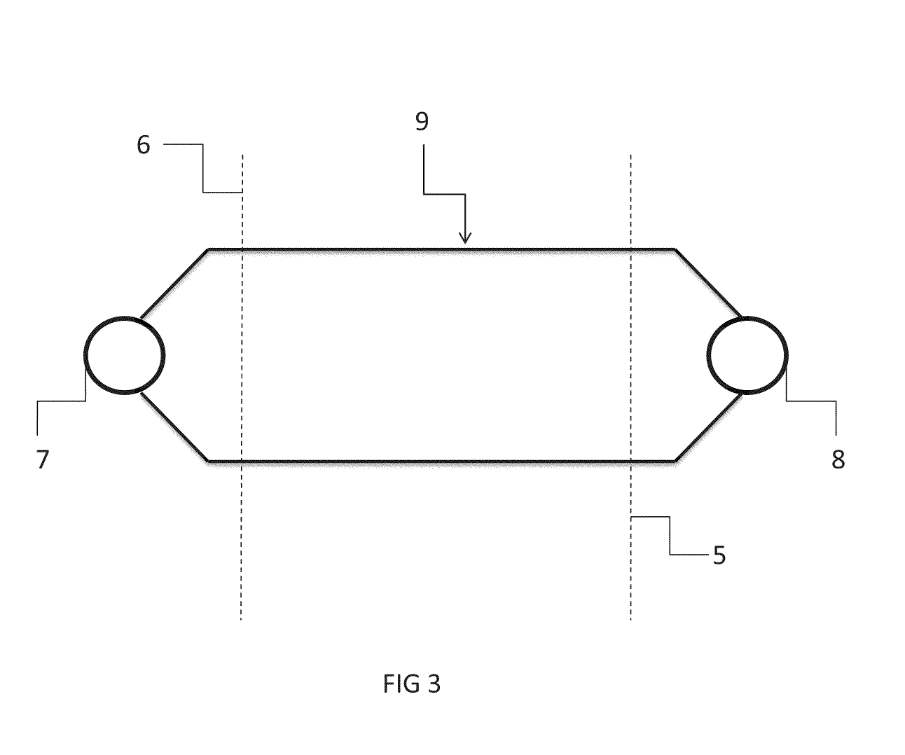

FIG. 3 illustrates a side perspective view of a thermoelectric module (TEM). As previously described, the backing 4 should provide some level of thermal conductivity to take full advantage of the power producing capability of the thermal gradient developed by the nocturnal radiation cooling effect. Practically speaking, the rigid backing 4 may also be referred to as the “earth” side 5, while the photovoltaic cells 2 may be referred to as the “space” side 6.

As current flows through a thermocouple 9, heat is transferred from the warm junction 8 of the thermocouple 9 to the cooler junction 7. So the current flow will tend to reduce the thermal gradient. But if heat from the “earth” side 5 of the improved solar panel 1 is in thermal contact with the “warm” thermocouple junctions 8 and the “cool” thermocouple junction 7 is either exposed to deep space or in thermal contact with the solar panels (which are then exposed to deep space), then the heat will be radiated off of the space side 6 and absorbed into the “earth” side 5. Consequently, the heat flow and current flow may continue throughout an entire night.

Although embodiments were inspired by the nocturnal radiation cooling effect, the apparatus may also provide additional electric power during daylight hours from a thermal gradient resulting from solar radiation. At night, the “space” side 6 of the improved solar panel 1 will become cooler than the earth side 5, but during the day, the “space” side 6 of the improved solar panel 1 is likely to become much warmer than the “earth” side 5 which is protected from solar radiation. Consequently, the TEMs may produce electrical energy during the day as well as at night.

The current state of the art in thermoelectric devices is the result of a strong emphasis in research and development for electronic cooling devices. The chips used in testing embodiments were all developed specifically for the purpose of electronic cooling, specifically, using electrical energy to create a thermal gradient (i.e., the Peltier effect). However, these chips were used for the reverse effect in testing these embodiments. Specifically, these chips were used for creating electrical energy from a thermal gradient (i.e., the Seebeck effect). While the two phenomena are essentially one, features of the chips that were used were optimized for generating a thermal gradient not generating electricity.

For instance, the density of thermocouples in the TEM used for cooling may be less than one that would be designed to generate electricity from a relatively small thermal gradient. The 10 degree Fahrenheit delta experienced during testing generated a tiny fraction of the current that the chip would be able to handle when used for electronic cooling. Consequently, a TEM optimized for generating electricity from the nocturnal radiation cooling effect may be denser and may produce more power than the ones used testing.

During testing, ten trials were run on ten different nights, with measurements taken every hour over a 15 hour period. In each trial, the voltage of the thermopile and the voltage of the solar cells were observed and recorded for both an improved solar panel and a control solar panel. The temperature on top on the solar panels and the temperature on the bottom of the solar panels were also observed and recorded.

A mean data table showing the measurements is shown below.

| | Top | Bottom | Diff | TEM | PV | Ctl |
|---|---|---|---|---|---|---|
| Hr | ° F. | ° F. | ° F. | mV | V | V |
| 1 | 47.4 | 50.6 | 3.2 | 9.3 | 0.6 | 0.6 |
| 2 | 45.3 | 49.8 | 4.5 | 11.5 | 0.2 | 0.2 |
| 3 | 43.7 | 48.2 | 4.5 | 12.3 | 0.0 | 0.0 |
| 4 | 42.7 | 47.4 | 4.7 | 13.3 | 0.0 | 0.0 |
| 5 | 41.3 | 46.5 | 5.2 | 14.2 | 0.0 | 0.0 |
| 6 | 39.9 | 44.9 | 5.0 | 15.0 | 0.0 | 0.0 |
| 7 | 38.7 | 43.3 | 4.6 | 15.2 | 0.0 | 0.0 |
| 8 | 38.1 | 42.1 | 4.0 | 15.0 | 0.0 | 0.0 |
| 9 | 37.0 | 41.7 | 4.7 | 16.0 | 0.0 | 0.0 |
| 10 | 37.2 | 41.1 | 3.9 | 15.2 | 0.0 | 0.0 |
| 11 | 37.3 | 41.1 | 3.8 | 15.2 | 0.0 | 0.0 |
| 12 | 36.6 | 41.3 | 4.7 | 16.2 | 0.0 | 0.0 |
| 13 | 36.5 | 41.4 | 4.9 | 15.8 | 0.0 | 0.0 |
| 14 | 38.1 | 41.8 | 3.7 | 14.3 | 0.1 | 0.1 |
| 15 | 39.7 | 43.0 | 3.3 | 12.8 | 0.5 | 0.5 |

The mean value of all of the thermopile voltages over the ten trials was 14.1 mV. The minimum value measured was 1.0 mV, the maximum value was 38.9 mV and the standard deviation was 11.5. This large standard deviation means that the measurements are not tightly clustered around the mean, but instead, are generally all over the range. The mean value of the thermopile voltages for trial 4 which was a cool, clear, calm night was 31.9 mV with a standard deviation of only 3.2, while the mean temperature difference between the top of the solar panel and bottom of the solar panel for that night was 7 degrees Fahrenheit.

From the trials it was determined that a single thermopile could produce approximately 1 milliwatt of power when the temperature difference between the top and bottom of the solar panel is 8 degrees Fahrenheit. From Ohm's law, the voltage was determined to be 35.9 mV, and the current was determined to be 29.9 milliamps. From that the power was determined to be approximately 0.001 watts (i.e., 1 mW).

The data shows conclusively that at least some power can be generated at night by a solar panel that is modified to include thermocouples. The nocturnal radiation cooling of the simulated solar panel consistently showed some temperature between the top and bottom of the panel at all hours of the night. The thermopile gave measureable voltage readings throughout all ten trials.

The testing trials were designed to simulate a stand-alone solar panel, elevated off the ground by approximately a meter. The solar panels may be mounted to a support structure that allows selection of a pitch, roll, and yaw of the solar panel. Solar panels and support structures such as these can be found on a solar farm. The solar panel itself may act as a roof, protecting the ground below it from the effects of nocturnal radiation cooling. The top of the solar panel will become cooler than the bottom of the solar panel at night. The simulated solar panels in these trials had only a single solar cell, but the size of the board was large enough to measure the effects of nocturnal radiation.

A 16,000 cm2 (160 cm×100 cm) solar panel could hold approximately 1,000 thermopile plates used in these trials since each thermopile plate was approximately 16 cm2 (4 cm×4 cm). As described above, the thermopile produced 1 mW of power. Therefore, a panel with 1,000 thermopile plates might produce 1 watt of power at night.

Most solar farms have thousands of solar panels. Some solar farms can produce as many as 20 megawatts (MW) of power during the day with 120,000 solar panels. If each of these panels produced 1 watt of power at night, the solar farm could produce 120 kilowatts (kW) of power (1 W/panel×120,000 panels). Consequently, on a clear, calm, winter night a solar farm could provide almost 1.7 MW-hours of electrical energy (120 kW×˜14 hours of darkness=1680 kW-hours). The winter daytime energy produced by the solar farm in the winter might be as much as 200 MW-hours (20 MW×10 hours of daylight=200 MW-hours). So the energy produced from the thermopiles of an improved solar panel may be almost 1% of the total energy by the solar farm (1.68 MW-hours/201.68 MW-hours=0.83%).

As previously mentioned, in certain embodiments, improved solar panels may be used on the roof of a home to supplement electrical power from the grid. The thermal gradient from nocturnal radiation may be substantially larger in these embodiments than on a solar farm. In a solar farm, the air circulates under and over the solar panels, carrying some of the heat from the bottom of the panel up to the cooler top, upsetting the temperature difference. If the panel is mounted onto a rooftop, less air can circulate under the panel, creating a warmer underside. The heat from the attic may jeep the bottom of the panel warm as well. The top of the panel may continue to cool off by nocturnal radiation.

In certain embodiments, the improved solar panels may also have electronics to control the direction of the flow of electricity to take advantage of daytime thermal gradients. For example, during the day, the space side 6 of the improved solar panel 1 may face direct sunlight. Consequently the space side 6 of the improved solar panel 1 may get substantially warmer than the earth side 5 of the improved solar panel 1, resulting in a flow of electricity reversed from nighttime operations.

Moreover, certain embodiments may be employed on space-based solar panels. Without air molecules, clouds, and pollution between an orbiting solar panel and deep space, the “dark” side of the improved solar panel may get quite cold while the “light” side may be warmed by solar radiation. With a substantially larger thermal gradient, the electrical energy available from the thermopiles may be even greater.

It is to be understood that the claims are not limited to the precise configuration and components illustrated above. Various modifications, changes and variations may be made in the arrangement, operation and details of the methods and apparatus described above without departing from the scope of the claims.

While the foregoing is directed to embodiments of the present disclosure, other and further embodiments of the disclosure may be devised without departing from the basic scope thereof, and the scope thereof is determined by the claims that follow.

1. An improved solar panel comprising:
an array of photovoltaic cells;
a thermally-conductive, rigid backing; and
an array of thermocouples sandwiched between and in thermal contact with the array of photovoltaic cells and the thermally conductive, rigid backing.

2. The improved solar panel of claim 1, wherein each photovoltaic cell of the array of photovoltaic cells comprise multicrystalline silicon.

3. The improved solar panel of claim 1, wherein the thermally-conductive, rigid backing is made from aluminum.

4. The improved solar panel of claim 1, wherein the thermally-conductive, rigid backing is shaped to enable roof-based mounting on an angled roof.

5. A solar power generation system comprising:
a plurality of solar panels, each panel comprising:
an array of photovoltaic cells,
a thermally-conductive, rigid backing, and
one or more thermopiles sandwiched between and in thermal contact with the array of photovoltaic cells and the thermally-conductive, rigid backing;
one or more support structures configured to elevate and position the plurality of solar panels; and
a control unit configured to alter the orientation of the one or more support structures.

6. The solar power generation system of claim 5, wherein each photovoltaic cell of the array of photovoltaic cells comprises multicrystalline silicon.

7. The solar power generation system of claim 5, wherein the thermally-conductive, rigid backing is made from aluminum.

8. The solar power generation system of claim 5, wherein the one or more support structures are configured to elevate the plurality of solar panels at least 1 meter above the ground.

9. The solar power generation system of claim 5, wherein the orientation of the one or more support structures affects the pitch and yaw of the solar panels.

10. A solar power generation system comprising:
a plurality of solar panels, each panel comprising:
an array of photovoltaic cells,
a thermally-conductive, rigid backing, and
one or more thermopiles sandwiched between and in thermal contact with the array of photovoltaic cells and the thermally-conductive, rigid backing; and
one or more support structures.

11. The solar power generation system of claim 10, wherein each photovoltaic cell of the array of photovoltaic cells comprises multicrystalline silicon.

12. The solar power generation system of claim 10, wherein the thermally-conductive, rigid backing is made from aluminum.

13. The solar power generation system of claim 10, wherein the one or more support structures are configured for roof mounting on a slanted roof.
